(19) United States
(12) Patent Application Publication
(10) Pub. No.: US 2024/0079344 A1
(43) Pub. Date: Mar. 7, 2024

(54) PACKAGING ASSEMBLY FOR SEMICONDUCTOR DEVICE AND METHOD OF MAKING

(71) Applicant: SHUNSIN TECHNOLOGY (ZHONG SHAN) LIMITED, Zhongshan (CN)

(72) Inventor: Shun-Hsing LIAO, Zhongshan City (CN)

(73) Assignee: SHUNSIN TECHNOLOGY (ZHONG SHAN) LIMITED, Zhongshan (CN)

(21) Appl. No.: 18/092,852

(22) Filed: Jan. 3, 2023

(30) Foreign Application Priority Data
Sep. 5, 2022 (CN) 202211080500.1

(51) Int. Cl. H01L 23/552; H01Q 1/22

(52) U.S. Cl. CPC H01L 23/552; H01Q 1/2283

(57) ABSTRACT

A packaging assembly for a semiconductor device and a method for manufacturing the packaging assembly includes a substrate, an electronic device, a molding layer and an electronic shielding layer. The substrate has first and second surfaces and a wiring layer. The electronic device is disposed on the substrate. The molding layer is formed on the first surface of the substrate to cover the electronic device and expose an exposed area of the first surface, the molding layer having a trench. The electronic shielding layer is formed on the periphery of the molding layer and is electrically connected to the wiring layer.

### FIELD

The subject matter herein generally relates to packaged semiconductor devices.

### BACKGROUND

Due to the demand for miniaturization of semiconductor devices, a reduced package size is required to meet the demands. There is a need not only for a miniaturized package structure, but also for additional functions.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a cross-sectional view of a packaged semiconductor device in accordance with an embodiment of the present disclosure.

FIGS. 2A, 2B, 2C, 2D, 2E and 2F are cross-sectional views of intermediate stages during manufacture of the semiconductor device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connect” means directly or indirectly connected through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

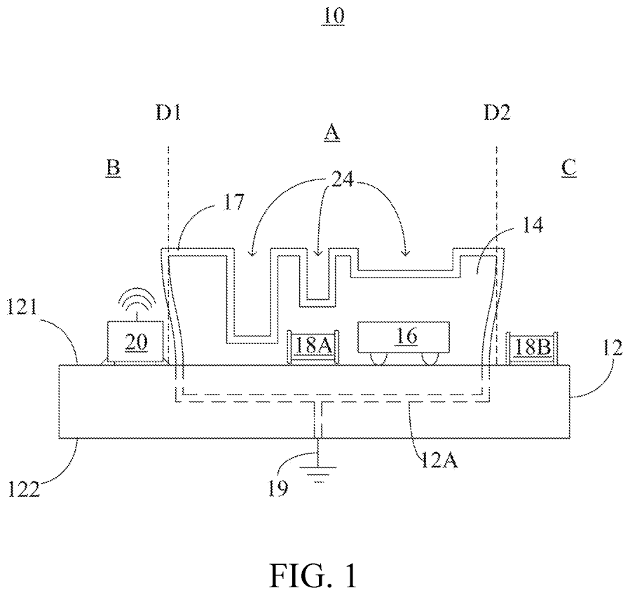

FIG. 1 is a cross-sectional view of a packaged semiconductor device 10 in accordance with an embodiment of the present disclosure. In one embodiment, the semiconductor device 10 includes a substrate 12, an encapsulation layer 14, one electronic device (first electronic device 16), another electronic device (second electronic device 20), electronic components (electronic devices 18A and 18B), and an electromagnetic shielding layer 17. In one embodiment, the substrate 12 can be a substrate of a double-layer or multi-layer circuit layer, for pre-processing procedures.

The pre-processing procedures includes providing a core board, forming the first conductive metal layer on the surface of the core board, and patterning the first conductive metal layer to form the first circuit layer. Next, build-up procedures are performed. An insulation layer is formed on the first circuit layer, and a second conductive metal layer is formed on the insulation layer. Afterwards, a second circuit layer is formed by patterning the second conductive metal layer. In this way, the substrate of the multi-layer circuit layer is formed by performing the build-up procedures as needed in cycles.

The insulation layer of the substrate 12 is made from insulating organic materials or ceramic materials, which can include, expoxyresin, polyimide, cyanate ester, glass fibers, bismaleimide triazine (BT), or a mixture of epoxy resin and glass fibers, for example. The conductive metal layer of the substrate 12 is made from conductive materials, which can include gold, silver, copper, aluminum, tungsten, tin, alloy or other suitable metals. Generally, copper with high conductivity is used as the wire material for the substrate 12 to transmit signals.

The insulation layer of the substrate 12 includes vias (through holes filled with conductive materials) to electrically connect circuit layers adjacent to the insulation layer. Moreover, the substrate 12 can be formed by laminated procedures and/or build-up procedures, well known to one having ordinary skill in the art and not repeated here.

The substrate 12 has a surface 121 (first surface, or the top surface of the substrate 12 in FIG. 1) and a surface 122 (second surface, or the bottom surface of the substrate 12 in FIG. 1) opposite to the surface 121.

The formation of the substrate 12 may involve multiple depositions or coating processes, patterning processes, and planarization processes. The depositions or coating processes can form insulating layers on the circuit layers 12A. The deposition or coating processes may include a spin coating process, an electroplating process, an electroless process, a chemical vapor deposition (CVD) process, a physical vapor deposition (PVD) process, an atomic layer deposition (ALD) process, and other applicable processes and combinations thereof.

The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a very flat top surface for the formed insulating layers and circuit layers 12A to facilitate subsequent processes. The planarization process may comprise a mechanical polishing process, a chemical mechanical polishing (CMP) process, or other applicable process and combinations thereof.

As shown in FIG. 1, the surface 121 of the substrate 12 has an area A, an area B, and an area C. The area A and the area B are bounded by the boundary line D1, and the area A and the area C are bounded by the boundary line D2. The electronic devices 16 and the electronic component 18A are disposed on the area A, the electronic device 20 is disposed on the area B, and the electronic component 18B is disposed on the area C. The area B and the area C are exposed, that is, not covered by the encapsulation layer 14.

There are two electronic devices 16 and 20 and two electronic components 18A and 18B shown in FIG. 1, but the number of the electronic devices 16 and 20 and the electronic components 18A and 18B is not limited thereto. One having ordinary skill in the art can modify the number of the electronic devices 16 and 20 and the electronic components 18A and 18B on the surface 121 of the substrate 12 according to actual needs.

Each electronic device 16 can be a semiconductor die, a semiconductor chip, or a package including electronic devices. The electronic devices 16 can be connected to the circuit layer 12A of the substrate 12 via conductive wires such as gold wires, copper wires, or aluminum wires. The electronic devices 16 may be optoelectronic devices, micro-electromechanical systems (MEMS), power amplifier chips, power management chips, biological identification devices, microfluidic systems, or physical sensors that measure changes in heat, light levels, and pressure. The electronic devices 16 also can also include semiconductor chips such as imaging sensor devices, light-emitting diodes (LEDs), solar cells, accelerators, gyroscopes, fingerprint readers, micro actuators, surface acoustic wave devices, or process sensors or ink printer heads made by a wafer scale package (WSP) process.

The electronic components 18A and 18B may be electrically connected to the circuit layer 12A of the substrate 12. According to an embodiment of the disclosure, the electronic components 18A and 18B may be passive, such as a resistor, a capacitor, an inductor, a filter, an oscillator, and so on. In other embodiments, the electronic components 18A and 18B may be electronic terminals.

The electronic devices 16 and 20 and the electronic components 18A and 18B can be disposed on the substrate 12 by a flip-chip packaging, and are electrically connected to the circuit layer 12A in the substrate 12. In one embodiment, the electronic devices 20 may be one or more antennas. The antenna component can be a loop antenna, a broadband dipole or monopole antenna, folded dipole antenna, a micro strip or patch antenna, a planar inverted-F antenna (PIFA), an inverted-F antenna (IFA), a tapered slot antenna (TSA), a slotted waveguide antenna, a half or quarter wave antenna, etc. The antenna component can be assembled with die attaching pads, lead fingers, tie bars, and additional conductive elements to form the antenna for different applications. These applications include wireless handheld devices that send and receive RF signals, such as smart phones, two-way communication devices, PC tablet computers, RF tags, sensors, Bluetooth and WI-FI devices, internet of things (IOT), home protection devices, remote controls, etc.

In addition, the electronic devices 16 and 20 and the electronic components 18A and 18B can also be disposed on the substrate 12 through an adhesive glue, and electrically connected to the circuit layer 12A in the substrate 12 by wire bonding. Therefore, the present disclosure can be implemented in flip-chip package, and can also be implemented in wire-bonded package by one having ordinary skill in the art.

According to an embodiment of the disclosure, the adhesive glue can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, poly methyl methacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

The encapsulation layer 14 is formed on the surface 121 of the substrate 12, and covers the electronic devices 16 and the electronic component 18A. In one embodiment, the encapsulation layer 14 is formed on a portion of the surface 121 of the substrate 12. In other words, the encapsulation layer 14 is formed only on the area A of the surface 121 of the substrate 12, and does not cover the areas B and C of the surface 121 of the substrate 12. The encapsulation layer 14 has grooves 24 on the top portion of the encapsulation layer 14.

In one embodiment, some grooves 24 can be formed on the top portion of the encapsulation layer 14 by mechanical drilling, etching, or laser drilling or by molding. The side walls adjacent to the top portion of the encapsulation layer 14 gradually converge toward the grooves 24. Therefore, the width of the bottom portion of the encapsulation layer 14 is less than the width of the top portion of the encapsulation layer 14. In other words, the projection area of the top portion of the encapsulation layer 14 on the substrate 12 is greater then the projection area of the bottom portion of the encapsulation layer 14 on the substrate 12. Moreover, the grooves 24 reduce the pressure on the electronic devices 16 and electronic component 18A when forming the encapsulation layer 14.

In one embodiment, the materials of the encapsulation layer 14 includes epoxy resin, cyanate ester, bismaleimide triazine, glass fiber, polybenzoxazole, polyimide, nitride (such as silicon nitride), oxide (such as silicon oxide), oxynitride Silicon, insulating materials, insulation organic materials, ceramic materials, or a mixture of epoxy resin and glass fiber.

In one embodiment, the electromagnetic shielding layer 17 is formed on the contour of the encapsulation layer 14, and is electrically connected to the circuit layer 12A of the substrate 12. As shown in FIG. 1, the electromagnetic shielding layer 17 is formed on the top portion of the encapsulation layer 14 and the inner surface of the grooves 24, and the inner surface of the grooves 24 may include the bottom portion surface and the side walls of the grooves 24. The electromagnetic shielding layer 17 has a uniform thickness. In other words, the thickness of the electromagnetic shielding layer 17 is fixed. The electromagnetic shielding layer 17 provides electromagnetic wave shielding to electronic components (such as the electronic devices 16 and the electronic component 18A) in the encapsulation layer 14, preventing electromagnetic interference (EMI). The electromagnetic wave may be generated by the electronic components out of the electromagnetic shielding layer 17, or by the electronic components within the electromagnetic shielding layer 17.

In one embodiment, the materials of the electromagnetic shielding layer 17 can be gold, silver, copper, aluminum, tungsten, tin, alloy or other suitable conductive material, and can be formed by metal evaporation, spraying, vacuum evaporation, sputtering, metal stamping, or casting. Moreover, the electromagnetic shielding layer 17 can be electrically connected to the ground potential 19 via the circuit layer 12A of the substrate 12, in order to achieve better electromagnetic wave shielding effect. In one embodiment, the electromagnetic shielding layer 17 and the surface 121 of the substrate 12 form an enclosed space. In another embodiment, as shown in FIG. 1, the electromagnetic shielding layer 17 and the circuit layer 12A in the substrate 12 form an enclosed space.

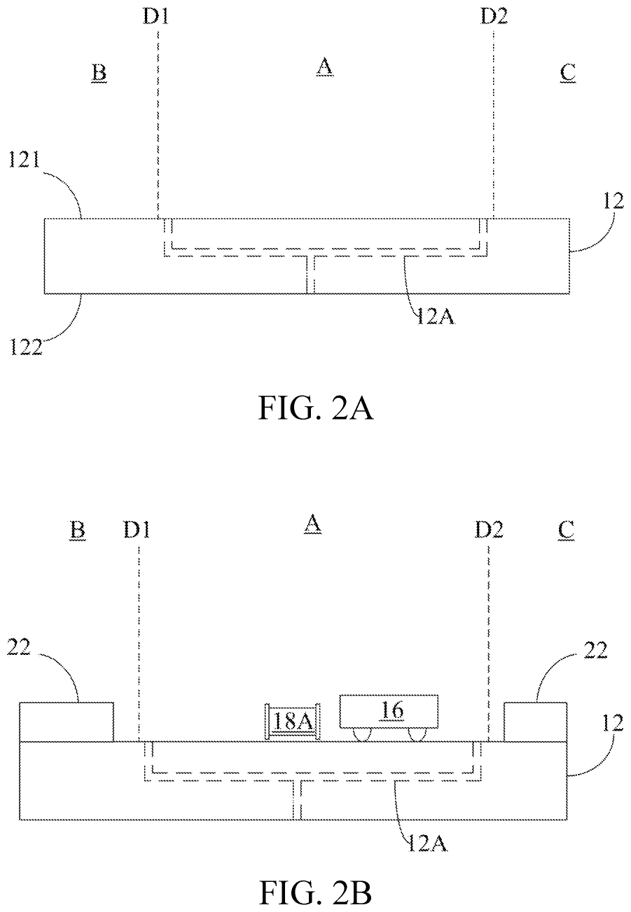

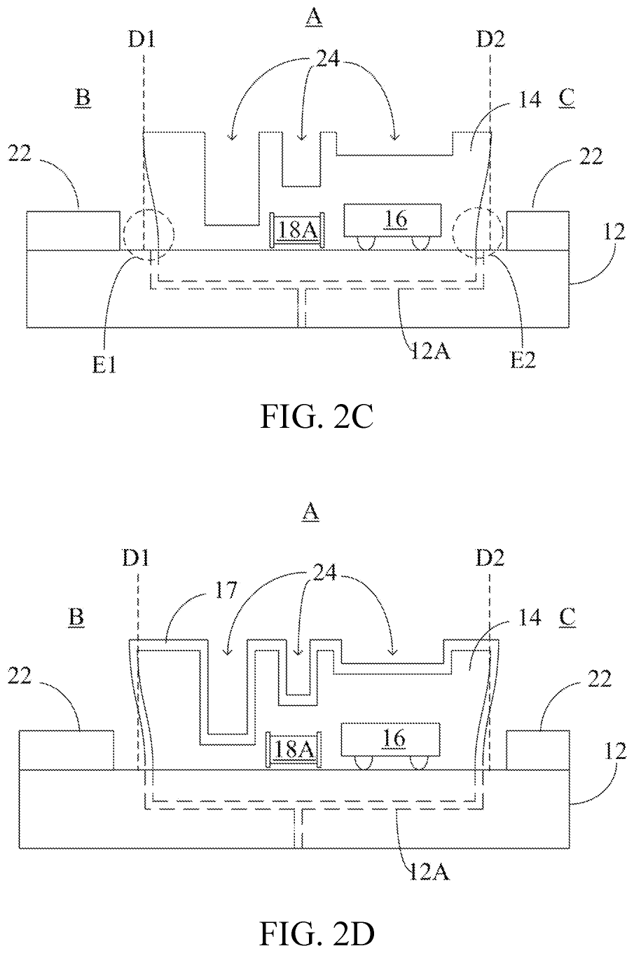

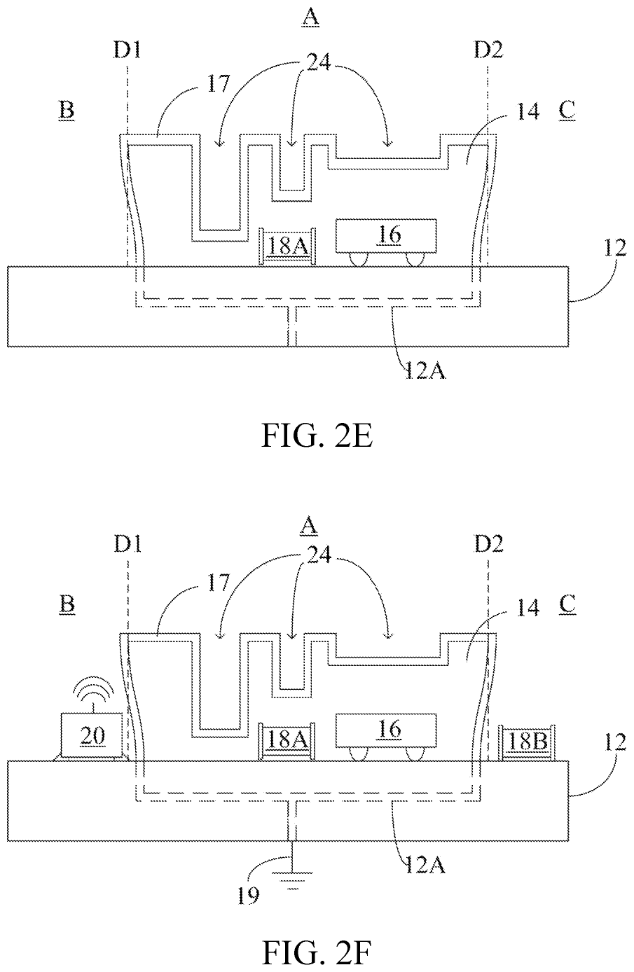

FIG. 2A to FIG. 2F are cross-sectional views of the intermediate stages of manufacture of the packaged semiconductor device. As shown in FIG. 2A, the substrate 12 are provided. The substrate 12 has one surface (first surface 121), another surface (second surface 122) opposite to the surface 121, and a circuit layer 12A. As shown in FIG. 1, the surface 121 of the substrate 12 has the area A, the area B, and the area C. The area A and the area B are bounded by the boundary line D1, and the area A and the area C are bounded by the boundary line D2. In one embodiment, the substrate 12 can be a substrate of a double-layer or multi-layer circuit layer, after pre-processing procedures are performed.

The pre-processing procedures includes providing a core board, forming the first conductive metal layer on the surface of the core board, and patterning the first conductive metal layer to form the first circuit layer. Next, build-up procedures are performed. An insulation layer is formed on the first circuit layer, and a second conductive metal layer is formed on the insulation layer. Afterwards, a second circuit layer is formed by patterning the second conductive metal layer. In this way, the substrate of the multi-layer circuit layer is formed by performing cycles of the build-up procedures as needed.

The insulation layer of the substrate 12 is made from insulation organic materials or ceramic materials, which can include expoxyresin, polyimide, cyanate ester, glass fibers, bismaleimide triazine (BT), or a mixture of epoxy resin and glass fibers, for example. The conductive metal layer of the substrate 12 is made from conductive materials, which can include gold, silver, copper, aluminum, tungsten, tin, alloy or other suitable metals. Generally, copper with high conductivity is mainly used as the wire material for the substrate 12 to transmit signals.

The insulation layer of the substrate 12 includes vias (through holes filled with conductive materials) to electrically connect circuit layers adjacent to the insulation layer. Moreover, the substrate 12 can be formed by laminated procedures and/or build-up procedures, well known to one having ordinary skill in the art and will not be repeated here for brevity.

In one embodiment, the formation of the substrate 12 may involve multiple deposition or coating processes, patterning processes, and planarization processes. The deposition or coating processes can form insulating layers on the circuit layers 12A. The deposition or coating processes may include a spin coating process, an electroplating process, an electroless process, a chemical vapor deposition (CVD) process, a physical vapor deposition (PVD) process, an atomic layer deposition (ALD) process, and other applicable processes and combinations thereof.

The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a very flat top surface for the formed insulating layers and circuit layers 12A to facilitate subsequent processes. The planarization process may comprise a mechanical polishing process, a chemical mechanical polishing (CMP) process, or other applicable process and combinations thereof.

Next, as shown in FIG. 2B, the electronic devices 16 and the electronic component 18A are disposed on the area A of the surface 121 of the substrate 12, and a barrier layer 22 is formed on the areas B and C of the surface 121. In one embodiment, the barrier layer 22 is made from insulating organic materials or ceramic materials, which can include epoxy resin, polyimide, cyanate ester, glass fiber, bismaleimide triazine (BT), or a mixture of epoxy resin and glass fibers.

Each electronic device 16 can be a semiconductor die, a semiconductor chip or a package including electronic devices. The electronic devices 16 can be connected to the circuit layer 12A of the substrate 12 via conductive wires such as gold wires, copper wires, or aluminum wires. The electronic devices 16 may be optoelectronic devices, micro-electromechanical systems (MEMS), power amplifier chips, power management chips, biological identification devices, microfluidic systems, or physical sensors that measure changes in heat, light levels, and pressure. The electronic devices 16 also can also include semiconductor chips such as imaging sensor devices, light-emitting diodes (LEDs), solar cells, accelerators, gyroscopes, fingerprint readers, micro actuators, surface acoustic wave devices, or process sensors or ink printer heads made by a wafer scale package (WSP) process.

The electronic components 18A and 18B may be electrically connected to the circuit layer 12A of the substrate 12. According to an embodiment of the disclosure, the electronic components 18A and 18B may be passive, such as a resistor, a capacitor, an inductor, a filter, an oscillator, and so on. In other embodiments, the electronic components 18A and 18B may be electronic terminals.

Next, as shown in FIG. 2C, the encapsulation layer 14 is formed on the surface 121 of the substrate 12, and covers the electronic devices 16 and the electronic component 18A. In one embodiment, the encapsulation layer 14 is formed on a portion of the surface 121 of the substrate 12. In other words, the encapsulation layer 14 is only formed on the area A of the surface 121 of the substrate 12, and does not cover the areas B and C of the surface 121 of the substrate 12. The encapsulation layer 14 has groove 24 on the top portion of the encapsulation layer 14.

In one embodiment, some grooves 24 can be formed on the top portion of the encapsulation layer 14 by mechanical drilling, etching, or laser drilling or molding. The side walls adjacent to the top portion of the encapsulation layer 14 gradually converge toward the grooves 24. Therefore, the width of the bottom portion of the encapsulation layer 14 is less than the width of the top portion of the encapsulation layer 14. In other words, the projection area of the top portion of the encapsulation layer 14 on the substrate 12 is greater than the projection area of the bottom portion of the encapsulation layer 14 on the substrate 12. Moreover, the grooves 24 reduce the pressure on the electronic devices 16 and electronic component 18A when forming the encapsulation layer 14.

In one embodiment, the materials of the encapsulation layer 14 includes epoxy resin, cyanate ester, bismaleimide triazine, glass fiber, polybenzoxazole, polyimide, nitride (such as silicon nitride), oxide (such as silicon oxide), oxynitride Silicon, insulating materials, insulation organic materials, ceramic materials, or a mixture of epoxy resin and glass fiber.

Next, as shown in FIG. 2D, the electromagnetic shielding layer 17 is formed on the contour of the encapsulation layer 14, and is electrically connected to the circuit layer 12A of the substrate 12. In this embodiment, the electromagnetic shielding layer 17 is formed on at least 90% of the exposed surface of the encapsulation layer 14, which excludes the bottom surface of the encapsulation layer 14 contacting the substrate 12. In one embodiment, the electromagnetic shielding layer 17 is formed on the whole of the exposed surface of the encapsulation layer 14.

As shown in FIG. 2D, the electromagnetic shielding layer 17 is formed on the top portion of the encapsulation layer 14 and the inner surface of the grooves 24, and the inner surface of the grooves 24 may include the bottom surface and the side wall of the grooves 24. The electromagnetic shielding layer 17 has a uniform thickness. Due to the existence of the barrier layer 22, the electromagnetic shielding layer 17 is not formed at the position where the barrier layer 22 is located.

The electromagnetic shielding layer 17 is used to provide electromagnetic wave shielding to electronic components (such as the electronic devices 16 and the electronic component 18A) in the encapsulation layer 14 to avoid electromagnetic interference (EMI). The electromagnetic wave may be generated by the electronic components out of the electromagnetic shielding layer 17, or by the electronic components within the electromagnetic shielding layer 17.

In one embodiment, the materials of the electromagnetic shielding layer 17 can be gold, silver, copper, aluminum, tungsten, tin, alloy or other suitable conductive material, and can be formed by metal evaporation, spraying, vacuum evaporation, sputtering, metal stamping, or casting. Moreover, the electromagnetic shielding layer 17 can be electrically connected to the ground potential 19 via the circuit layer 12A of the substrate 12, in order to achieve better electromagnetic wave shielding effect. In one embodiment, the electromagnetic shielding layer 17 and the surface 121 of the substrate 12 form an enclosed space. In another embodiment, as shown in FIG. 1, the electromagnetic shielding layer 17 and the circuit layer 12A in the substrate 12 form an enclosed space.

Next, as shown in FIG. 2E, the barrier layer 22 is removed. The electromagnetic shielding layer 17 is not disposed on the area, on which the barrier layer 22 is disposed, so as to avoid short circuit. Next, as shown in FIG. 2F, the electronic devices 20 and the electronic component 18B are disposed on the areas B and C. Since the side walls of the encapsulation layer 14 gradually converge toward the grooves 24, a larger space is provided for placing electronic devices 20 and electronic components 18B.

In one embodiment, the electronic devices 16 and 20 and the electronic components 18A and 18B can be disposed on the substrate 12 by a flip-chip packaging, and are electrically connected to the circuit layer 12A in the substrate 12. In one embodiment, the electronic devices 20 may be an antenna component. The antenna component can be a loop antenna, a broadband dipole or monopole antenna, folded dipole antenna, a micro strip or patch antenna, a planar inverted-F antenna (PIFA), an inverted-F antenna (IFA), a tapered slot antenna (TSA), a slotted waveguide antenna, a half or quarter wave antenna, etc. The antenna component can be assembled with die attach pads, lead fingers, tie bars, and additional conductive elements to form the antenna for different applications. These applications include wireless handheld devices that need to send and receive RF signals, such as smart phones, two-way communication devices, PC tablet computers, RF tags, sensors, Bluetooth and WI-FI devices, internet of things (IOT), home protection devices, remote controls, etc.

In addition, the electronic devices 16 and 20 and the electronic components 18A and 18B can also be disposed on the substrate 12 through an adhesive glue, and are electrically connected to the circuit layer 12A in the substrate 12 by wire bonding. Therefore, the present disclosure can be implemented in flip-chip package, and can also be implemented in wire-bonded package by one having ordinary skill in the art.

According to an embodiment of the disclosure, the adhesive glue can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

According to the embodiments of the disclosure, the grooves formed in the encapsulation layer reduce the pressure on electronic devices when forming the encapsulation layer, and avoid damage to electronic devices. Moreover, the grooves formed in the encapsulation layer increase the area of the encapsulation layer, thereby increasing the area of the electromagnetic shielding layer formed on the surface of the encapsulation layer, which can improve the electrical shielding effect. In addition, since the bottom of the side walls of the encapsulation layer converge toward the center of the encapsulation layer, more space is provided for setting electronic devices or other functional components, which effectively improves the integration density of the semiconductor device and achieves the goal of miniaturization of the semiconductor device.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A semiconductor device comprising:
a substrate comprising a first surface, a second surface opposite to the first surface, and a circuit layer;
a first electronic device disposed on substrate;
an encapsulation layer formed on the first surface of the substrate, the encapsulation layer covering the first electronic device and be separated from an exposed area of the first surface, wherein the encapsulation layer has a groove; and
an electromagnetic shielding layer formed on the encapsulation layer, the electromagnetic shielding layer being electrically connected to the circuit layer.

2. The semiconductor device as claimed in claim 1, wherein the electromagnetic shielding layer is further formed on a bottom surface and a side wall of the groove.

3. The semiconductor device as claimed in claim 1, wherein the electromagnetic shielding layer is formed on a surface of the encapsulation layer, and has a uniform thickness.

4. The semiconductor device as claimed in claim 1, wherein the encapsulation layer has a top portion and a side wall, the groove is formed on the top portion, the side wall converges to the groove.

5. The semiconductor device as claimed in claim 1, wherein the encapsulation layer has a top portion, a bottom portion, and a side wall, the groove is formed on the top portion, and a width of the top portion is greater than a width of the bottom portion.

6. The semiconductor device as claimed in claim 1, wherein the electromagnetic shielding layer and the substrate forms an enclosed space.

7. The semiconductor device as claimed in claim 1, wherein the electromagnetic shielding layer and the circuit layer forms an enclosed space.

8. The semiconductor device as claimed in claim 1, further comprising a plurality of second electronic devices disposed on the exposed area of the first surface of the substrate.

9. The semiconductor device as claimed in claim 8, wherein each of the plurality of second electronic devices is an antenna component.

10. The semiconductor device as claimed in claim 1, wherein the circuit layer is coupled to a ground potential.
